(19) United States
(12) Patent Application Publication
(10) Pub. No.: US 2026/0351330 A1
(43) Pub. Date: Nov. 5, 2026

(54) DATA STORAGE DEVICE, SEMICONDUCTOR DEVICE, AND METHOD OF TESTING SEMICONDUCTOR DEVICE

(71) Applicant: SK hynix Inc., Icheon-si (KR)

(72) Inventors: Hyun Joon Lee, Icheon-si (KR); Sung Hoon On, Icheon-si (KR)

(21) Appl. No.: 19/713,327

(22) Filed: Jun. 18, 2026

(30) Foreign Application Priority Data
Mar. 23, 2006 (KR) 10-2026-0051658

(51) Int. Cl. G11C 29/02; G11C 29/04; G11C 29/12

(52) U.S. Cl. CPC G11C 29/028; G11C 29/12005; G11C 2029/0401

(57) ABSTRACT

A semiconductor device includes at least one trimming target circuit generating a plurality of analog output values according to a plurality of trim codes, and a trimming control circuit performing a search operation of sequentially outputting the trim codes, receiving the analog output values corresponding to the trim codes and outputting from the at least one trimming target circuit. When a sign of a first difference value between a target value and a first analog output value corresponding to a first trim code has a first sign, a second difference value between the target value and a second analog output value corresponding to a second trim code has a second sign different from the first sign, and an absolute value of the first difference value is smaller than that of the second difference value, the trimming control circuit may determine the first trim code as a final trim code.

### CROSS-REFERENCE TO RELATED APPLICATION

The present application claims priority under 35 U.S.C. § 119(a) to Korean patent application number 10-2026-0051658 filed on Mar. 23, 2026, which is incorporated herein by reference in its entirety.

### BACKGROUND

### 1. Technical Field

Embodiments of the present disclosure relate to a data storage device, a semiconductor device, and a method of testing a semiconductor device.

### 2. Related Art

A data storage device may include at least one memory configured to store data. The data storage device may include a controller configured to control an operation of the at least one memory.

A semiconductor device may perform a trim code search operation based on a test mode signal received from an external device. Alternatively, in some cases, the semiconductor device may perform the trim code search operation based on an internal command.

The semiconductor device generates analog output values having various levels according to trim codes, and the generated analog output values are used for various operations such as program, read, and erase operations.

### SUMMARY

The objects of embodiments of the present disclosure are not limited to those described herein, and other objects not explicitly mentioned may be apparent to those skilled in the art from the description below.

Embodiments of the present disclosure may quickly and accurately determine a trim code corresponding to a predetermined target value in a semiconductor device, thereby effectively correcting a deviation of an analog output value and improving operational stability and reliability of the semiconductor device.

Embodiments of the present disclosure may provide a semiconductor device comprising: at least one trimming target circuit configured to generate a plurality of analog output values according to a plurality of trim codes; and a trimming control circuit configured to perform a search operation of sequentially outputting the trim codes, and receive the analog output values corresponding to the trim codes and outputting from the at least one trimming target circuit, the analog output values including first and second analog output values respectively corresponding to first and second trim codes of the trim codes. The trimming control circuit is configured to determine the first trim code as a final trim code, when a first difference value between a target value and the first analog output value corresponding to the first trim code has a first sign, a second difference value between the target value and the second analog output value corresponding to the second trim code has a second sign that is different from the first sign, and an absolute value of the first difference value is smaller than that of the second difference value.

Embodiments of the present disclosure may provide a method of testing a semiconductor device, comprising: receiving a test mode signal from a tester; sequentially outputting a plurality of trim codes when the test mode signal is received; generating a plurality of analog output values according to the plurality of trim codes, the analog output values including first and second analog output values respectively corresponding to first and second trim codes of the trim codes; determining a first difference value between the first analog output value and a target value and a second difference value between the second analog output value and the target value; and determining the first trim code as a final trim code when a first sign of the first difference value is different from a second sign of the second difference value and an absolute value of the first difference value is smaller than that of the second difference value.

Embodiments of the present disclosure may provide a data storage device comprising: at least one memory; and a controller including at least one trimming target circuit configured to generate a plurality of analog output values according to a plurality of trim codes, and a trimming control circuit configured to output the trim codes. The trimming control circuit is configured to: perform a search operation of sequentially outputting the trim codes; receive the analog output values corresponding to the trim codes and outputting from the at least one trimming target circuit, the analog output values including first and second analog output values respectively corresponding to first and second trim codes of the trim codes; and determine the first trim code as a final trim code, when a first difference value between a target value and the first analog output value has a first sign, a second difference value between the target value and the second analog output value has a second sign that is different from the first sign, and an absolute value of the first difference value is smaller than that of the second difference value.

According to embodiments of the present disclosure, a trim code corresponding to a predetermined target value can be quickly and accurately determined in a semiconductor device, so that a deviation of an analog output value can be effectively corrected and operational stability and reliability of the semiconductor device may be improved.

Various effects of embodiments of the present disclosure are not limited to the effects mentioned above, and other effects not mentioned may be understood by those skilled in the art from the description of the claims.

### BRIEF DESCRIPTION OF THE DRAWINGS

The present disclosure will be more clearly understood from the following detailed description and the accompanying drawings, which are provided for illustrative purposes only and are not intended to limit the scope of the present disclosure.

FIG. 1 is a diagram illustrating a schematic configuration of a semiconductor device according to embodiments of the present disclosure.

FIG. 2 is a diagram illustrating a linear search method of a trimming control circuit according to embodiments of the present disclosure.

FIG. 3 is a diagram illustrating a binary search method of a trimming control circuit according to embodiments of the present disclosure.

FIG. 4 is a diagram illustrating a coarse search method of a trimming control circuit according to embodiments of the present disclosure.

FIG. 5 is a diagram illustrating a coarse search method under a condition in which an analog output value changes exponentially, according to embodiments of the present disclosure.

FIG. 6 is a diagram illustrating a coarse search and SRS search method of a trimming control circuit according to embodiments of the present disclosure.

FIG. 7 is a diagram illustrating a coarse search and SRS search method of a trimming control circuit according to embodiments of the present disclosure.

FIG. 8 is a flowchart illustrating a trim code search process according to a coarse search and SRS search method of a trimming control circuit according to embodiments of the present disclosure.

FIG. 9 is a diagram illustrating a method of testing a semiconductor device according to embodiments of the present disclosure.

FIG. 10 is a diagram illustrating a schematic configuration of a data storage device according to embodiments of the present disclosure.

### DETAILED DESCRIPTION

In the following description of examples or embodiments of the present disclosure, reference will be made to the accompanying drawings in which it is shown by way of illustration of specific examples or embodiments that may be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein may be omitted for the interest of brevity. The terms such as “including,” “having,” “containing,” “constituting,” “made up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the present disclosure. Each of these terms is not used to define essence, order, sequence, or number of elements etc., but is used merely to distinguish the corresponding element from other elements.

When a first element “is connected or coupled to,” “contacts or overlaps” or the like, a second element, not only can the first element “be directly connected or coupled to” or “directly contact or overlap” the second element, but one or more intervening elements can also be “interposed” between the first and second elements.

When time relative terms, such as “after,” “subsequent to,” “next,” “before,” and the like, are used to describe processes or operations of elements or configurations, or flows or steps in operating, processing, or manufacturing methods, these terms may be used to describe non-consecutive or non-sequential processes or operations unless the term “directly” or “immediately” is used together.

In addition, when any dimensions, relative sizes etc. are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

Hereinafter, some embodiments of the present disclosure will be described in detail with reference to accompanying drawings.

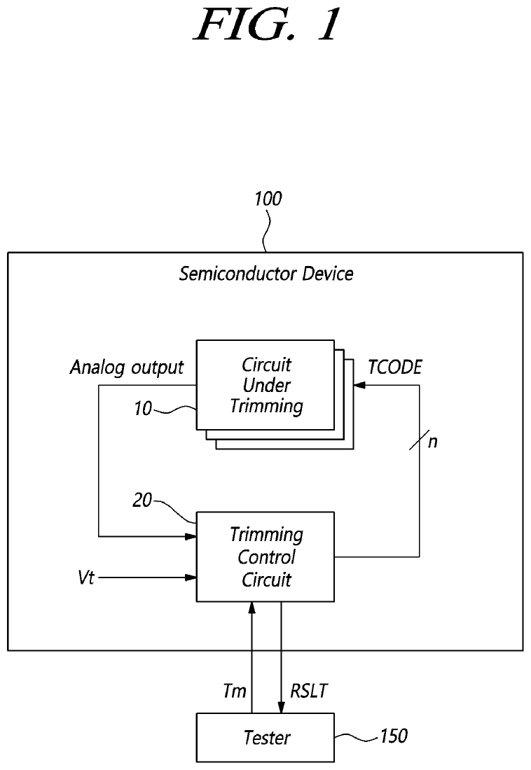

FIG. 1 is a diagram illustrating a schematic configuration of a semiconductor device 100 according to embodiments of the present disclosure.

Referring to FIG. 1, the semiconductor device 100 according to embodiments of the present disclosure may include at least one trimming target circuit 10 configured to generate an analog output value according to a predetermined trim code, and a trimming control circuit 20 configured to perform a search operation of sequentially outputting the trim code, receive the analog output value corresponding to the trim code and outputting from the at least one trimming target circuit 10, and, when a sign of a difference value between the received analog output value and a predetermined target value is changed, determine a trim code corresponding to an analog output value having a smallest absolute difference from the target value among analog output values before and after the sign is changed as a final trim code. For example, at least one trimming target circuit 10 may generate a plurality of analog output values (Analog output) according to a plurality of trim codes (TCODE), respectively, and a trimming control circuit 20 may perform a search operation of sequentially outputting the trim codes (TCODE), and receive the analog output values (Analog output) corresponding to the trim codes (TCODE) and outputting from the at least one trimming target circuit 10. When a first difference value between a target value and a first one of the analog output values (Analog output) corresponding to a first one of the trim codes (TCODE) has a first sign, a second difference value between the target value and a second one of the analog output values (Analog output) corresponding to a second one of the trim codes (TCODE) has a second sign that is different from the first sign, and an absolute value of the first difference value is smaller than that of the second difference value, the trimming control circuit 20 may determine the first one of the trim codes as a final trim code.

The trimming control circuit according to embodiments of the present disclosure may further include a trim code temporary storage unit configured to store the final trim code, and may set the final trim code stored in the trim code temporary storage unit as an initial trim code before re-performing the search operation.

The semiconductor device 100 may include a trimming target circuit 10 and a trimming control circuit 20. The semiconductor device 100 may operate in a test mode under control of a tester 150.

In the semiconductor device 100, variations in electrical characteristics may occur due to fluctuations in process conditions occurring in a manufacturing process. Such process variations may cause changes in threshold voltage, resistance value, capacitance value, mobility, etc., of transistors, and accordingly, an error may occur between an analog output value (Analog output or Output) of the trimming target circuit 10 and a target value (Target_value) set in a design stage. The trimming control circuit 20 may compensate for the error of the analog output value (Output) due to the process variation by determining a final trim code (Fin. Code) corresponding to an analog output value (Output) closest to the target value (Target_value) through a trim code search operation.

The trimming target circuit 10 may generate the analog output value (Output) according to a given (e.g., predetermined) trim code (TCODE). The trimming target circuit 10 may generate at least one analog output value (Output) among voltage, current, or frequency according to each trim code (TCODE).

The trimming target circuit 10 may be an analog signal generation circuit configured to generate at least one of voltage, current, or frequency (e.g., a signal with the frequency). For example, the trimming target circuit 10 may include a bandgap reference voltage circuit (BGR) configured to generate a reference voltage, a low drop-out regulator (LDO) configured to generate an internal driving voltage, an oscillator (OSC) configured to generate a reference clock signal with a specific frequency, and a current generation circuit configured to generate a reference current.

The trimming target circuit 10 may include 2^{N} output levels corresponding to an N-bit trim code. The trim code and the analog output value (Output) may have a monotonically increasing or monotonically decreasing relationship in the entire code section or at least a partial code section. A difference or a ratio between two analog output values (Output) respectively corresponding to neighboring trim codes may be defined as a code offset.

For example, when the trimming target circuit 10 is configured to output voltage or current, the code offset may be defined as a difference value between two analog output values (Output) respectively corresponding to neighboring trim codes. In addition, when the trimming target circuit 10 is configured to output a frequency, the code offset may be defined as a ratio of two analog output values (Output) respectively corresponding to neighboring trim codes.

The trimming control circuit 20 is connected to the tester 150, and may perform a test operation such as generating a trim code (TCODE) in response to a test mode signal (Tm) of the tester 150, and provide a test result (RSLT) to the tester 150.

In one embodiment, the trimming control circuit 20 may be implemented in the form of a built-in self-test (BIST) device. Accordingly, various tests including a trimming control operation may be performed on-chip. The trimming control circuit 20 may provide the test result (RSLT) to the tester 150 after completing the trimming control operation.

The trimming control circuit 20 may perform a search operation of outputting the trim code (TCODE) such that the analog output value (Output) output from the trimming target circuit 10 approaches a predetermined target value (Target_value). For example, the trimming control circuit 20 may perform a search operation of sequentially outputting a plurality of trim codes (TCODE). This may be referred to as a linear search method.

The trim code (TCODE) may consist of a plurality of bits. For example, if the trim code (TCODE) consists of 6 bits, the trimming control circuit 20 may include 64 (=2⁶) trim codes (TCODE). The trimming target circuit 10 may generate 64 analog output values (Output) according to the trim codes (TCODE), respectively.

The predetermined target value (Target_value) may be a reference value received from an external device or stored inside the semiconductor device 100. In one embodiment, when the trimming target circuit 10 is a bandgap reference voltage circuit (BGR) or a low drop-out regulator (LDO) that generates a reference voltage, the predetermined target value (Target_value) may be a reference voltage value. In one embodiment, when the trimming target circuit 10 is an oscillator (OSC) that generates a reference clock signal, the predetermined target value (Target_value) may be a target frequency value of the reference clock signal. In one embodiment, when the trimming target circuit 10 is a current generation circuit that generates a reference current, the predetermined target value (Target_value) may be a reference current value. However, embodiments of the present disclosure are not limited thereto.

The trimming control circuit 20 may receive, from the at least one trimming target circuit 10, the analog output value (Output) output based on the trim code (TCODE). The trimming control circuit 20 may include a detector (not shown) for measuring the analog output value (Output) output from the trimming target circuit 10. The detector (not shown) of the trimming control circuit 20 may detect the analog output value (Output) and convert the analog output value (Output) into a digital value or a comparison signal. The trimming control circuit 20 may perform a comparison operation between a predetermined target value (Target_value) and the digital value or the comparison signal corresponding to the analog output value (Output). However, embodiments of the present disclosure are not limited thereto.

The trimming control circuit 20 may include a comparator (not shown) for comparing a difference between the received analog output value (Output) and a predetermined target value (Target_value). The comparator (not shown) of the trimming control circuit 20 may receive the analog output value (Output) and the target value (Target_value), calculate a difference value between the analog output value (Output) and the target value (Target_value), and determine a magnitude and a sign of the difference value. In other words, the comparator (not shown) of the trimming control circuit 20 may determine whether the difference value between the analog output value (Output) and the target value (Target_value) has a first sign (e.g., a positive (+) sign) or a second sign (e.g., a negative (−) sign).

The trimming control circuit 20 may set a criterion for outputting the trim code (TCODE) according to the sign of the difference value between the analog output value (Output) corresponding to the trim code (TCODE) and outputting from the trimming target circuit 10 and the target value (Target_value). In some embodiments, the trimming control circuit 20 may set a criterion for outputting each of the trim codes (TCODE) according to a sign of a difference value between the target value (Target_value) and the analog output value (Output) corresponding to a previous trim code (TCODE). For example, when the analog output value (Output) is smaller than the target value (Target_value), the trimming control circuit 20 may determine that the difference value between the analog output value (Output) and the target value (Target_value) has a negative (−) sign. In this case, if the analog output value (Output) is configured to monotonically increase as the trim code (TCODE) increases, the trimming control circuit 20 may output a trim code having a larger value than a previous trim code to increase the analog output value (Output).

In addition, the comparator (not shown) of the trimming control circuit 20 may check whether the sign of the difference value between the analog output value (Output) and the target value (Target_value) is changed. When the sign of the difference value between the analog output value (Output) and the target value (Target_value) is changed, the comparator (not shown) of the trimming control circuit 20 may determine that the target value (Target_value) exists between two analog output values before and after the sign is changed.

When the sign of the difference value between the received analog output value (Output) and the predetermined target value (Target_value) is changed, the trimming control circuit 20 may determine a trim code (TCODE) corresponding to an analog output value (Output) having a smaller absolute difference from the target value (Target_value) among analog output values before and after the sign is changed as a final trim code (Fin. Code).

The trimming control circuit 20 may include a trim code temporary storage unit (not shown) configured to store the final trim code (Fin. Code). In one embodiment, when a tolerance range is exceeded or a condition for repeating the search is satisfied, the trimming control circuit 20 may set the final trim code (Fin. Code) stored in the trim code temporary storage unit (not shown) as an initial trim code before re-performing the search operation. By using the final trim code (Fin. Code) determined by the existing search operation as a starting point of the repeated search, the search operation may be performed in a region relatively close to the target value (Target_value) rather than the entire trim code array range.

Accordingly, the trim code search range may be reduced during the repeated search, and unnecessary trim code output and measurement operations may be decreased.

Hereinafter, various trim code search operations for determining the final trim code (Fin. Code) will be described.

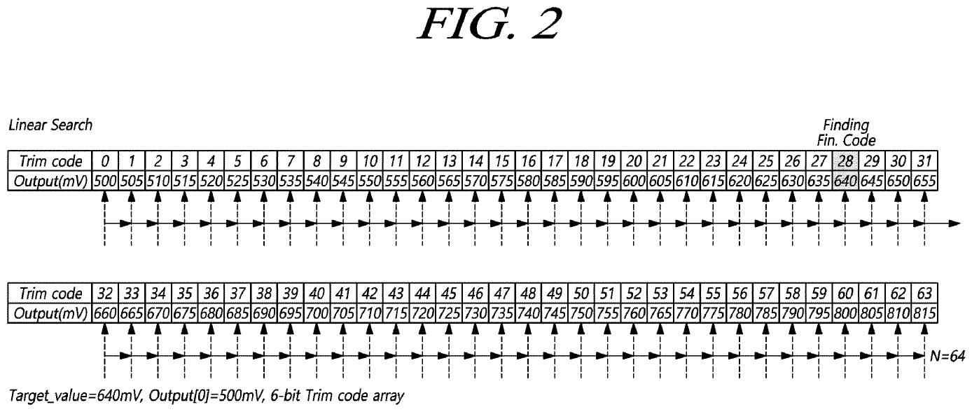

FIG. 2 is a diagram illustrating a linear search method of the trimming control circuit 20 according to embodiments of the present disclosure.

Referring to FIG. 2, it is assumed that the trimming control circuit 20 outputs a 6-bit trim code (TCODE). Accordingly, the trimming control circuit 20 may output 64 (=2⁶) trim codes (TCODE).

In FIG. 2, a set of a plurality of trim codes used to adjust the analog output value (Output) of the trimming target circuit 10 may be represented as a trim code array. The trim code array may indicate a set of a plurality of trim codes that can be provided to the trimming target circuit 10. Each trim code (TCODE) affects the analog output value (Output) of the trimming target circuit 10, and the trimming control circuit 20 may determine a trim code (TCODE) corresponding to an analog output value closest to the target value (Target_value) among the plurality of trim codes as the final trim code (Fin. Code).

For convenience of description, in FIG. 2, the trimming target circuit 10 may be a bandgap reference voltage circuit (BGR) or a low drop-out regulator (LDO) configured to generate a reference voltage. However, embodiments of the present disclosure are not limited thereto.

In the embodiment of FIG. 2, an initial analog output value (Output[0]) corresponding to a 0-th trim code (Trim code 0) may be 500 mV, and the target value (Target_value) may be 640 mV. In addition, a code offset, which is a difference between two analog output values (Output) respectively corresponding to neighboring trim codes, may be 5 mV. In other words, as the trim code (TCODE) increases by 1, the analog output value (Output), i.e., the output voltage, may increase by a predetermined voltage unit (e.g., 5 mV) from 500 mV, which is the initial analog output value (Output[0]) corresponding to the 0-th trim code (Trim code 0).

The analog output value (Output) of the trimming target circuit 10 may be a fixed value set in the design stage of the semiconductor device, but may be changed in the process stage.

The trimming control circuit 20 may output an initial trim code (e.g., Trim code 0) to the trimming target circuit 10 at a search start time. The trimming target circuit 10 may generate the analog output value (Output) in response to the initial trim code (Init. Code). The trimming control circuit 20 may measure the analog output value (Output) through a detector (not shown). This process may be referred to as a search operation or a trimming operation.

The trimming control circuit 20 may measure the analog output value (Output) corresponding to each trim code (TCODE) in a manner of increasing the trim code (TCODE) by 1 from the initial trim code (e.g., Trim code 0) (0→1→2→. . . →63). In FIG. 2, arrows exemplarily illustrate such a linear search method.

Since the linear search is a method of sequentially checking the analog output value (Output) corresponding to each of all trim codes in the trim code array, a maximum of N measurements may be required when the number of trim codes is N.

For example, the trimming control circuit 20 may stop the search operation after measuring all analog output values (Output) respectively corresponding to the trim codes included in the 6-bit trim code array. In other words, the trimming control circuit 20 may stop the search operation after performing 64 search operations.

The trimming control circuit 20 may calculate an absolute value of a difference value between the measured analog output value (Output) and the predetermined target value (Target_value). Subsequently, the trimming control circuit 20 may determine a trim code (TCODE) corresponding to an analog output value (Output) closest to or substantially equal to the predetermined target value (Target_value) as the final trim code (Fin. Code). For example, the trimming control circuit 20 may determine the 28-th trim code (Trim code 28) corresponding to an analog output value (Output) equal to 640 mV, which is the predetermined target value (Target_value), as the final trim code (Fin. Code).

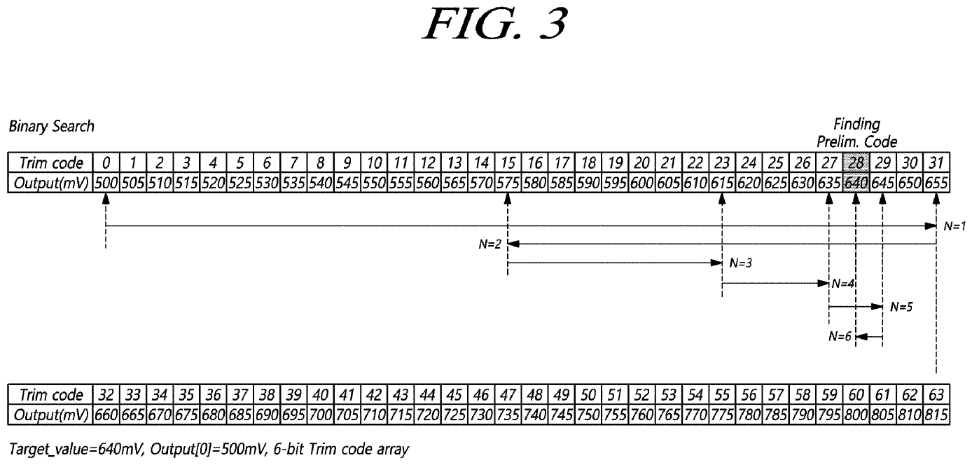

FIG. 3 is a diagram illustrating a binary search method of the trimming control circuit 20 according to embodiments of the present disclosure.

Referring to FIG. 3, it is assumed that the trimming control circuit 20 outputs a 6-bit trim code (TCODE). Accordingly, the trimming control circuit 20 may output 64 (=2⁶) trim codes (TCODE).

In FIG. 3, a set of a plurality of trim codes used to adjust the analog output value (Output) of the trimming target circuit 10 may be represented as a trim code array. The trim code array may indicate a set of a plurality of trim codes that can be provided to the trimming target circuit 10. Each trim code (TCODE) affects the analog output value (Output) of the trimming target circuit 10, and the trimming control circuit 20 may determine a trim code (TCODE) corresponding to an analog output value closest to the target value (Target_value) among the plurality of trim codes as the final trim code (Fin. Code).

For convenience of description, in FIG. 3, the trimming target circuit 10 may be a bandgap reference voltage circuit (BGR) or a low drop-out regulator (LDO) configured to generate a reference voltage. However, embodiments of the present disclosure are not limited thereto.

In the embodiment of FIG. 3, an initial analog output value (Output[0]) corresponding to a 0-th trim code (Trim code 0) may be 500 mV, and the target value (Target_value) may be 640 mV. In addition, a code offset, which is a difference between two analog output value (Output) respectively corresponding to neighboring trim codes, may be 5 mV. In other words, as the trim code (TCODE) increases by 1, the analog output value (Output), i.e., the output voltage, may increase by a predetermined voltage unit (e.g., 5 mV) from 500 mV, which is the initial analog output value (Output[0]) corresponding to the 0-th trim code (Trim code 0).

The analog output value (Output) of the trimming target circuit 10 may be a fixed value set in the design stage of the semiconductor device, but may be changed in the process stage.

The trimming control circuit 20 may output an initial trim code (e.g., Trim code 0) to the trimming target circuit 10 at the search start time. The trimming target circuit 10 may generate the initial analog output value (Output[0]) in response to the initial trim code (Init. Code). The trimming control circuit 20 may measure the analog output value (Output) through a detector (not shown). This process may be referred to as a search operation or a trimming operation.

The trimming control circuit 20 may measure the analog output value (Output) corresponding to each trim code (TCODE) by repeatedly dividing trim codes included in the trim code array into two sections.

For example, the trimming control circuit 20 may output the 31-st trim code (Trim code 31) corresponding to a median value among the 64 trim codes capable of being output by the trimming control circuit 20.

Subsequently, the trimming control circuit 20 may compare a predetermined target value (e.g., 640 mV) with an analog output value (e.g., 655 mV) corresponding to the 31-st trim code (Trim code 31). The trimming control circuit 20 may set a trim code search range in which the search operation is to be performed in the trim code array according to the comparison result. For example, the trimming control circuit 20 may perform the search operation on trim codes located between the 0-th trim code (Trim code 0) and the 31-st trim code (Trim code 31). The trimming control circuit 20 may output the 15-th trim code (Trim code 15) corresponding to a median value between the 0-th trim code (Trim code 0) and the 31-st trim code (Trim code 31).

Subsequently, the trimming control circuit 20 may compare the predetermined target value (e.g., 640 mV) with an analog output value (e.g., 575 mV) corresponding to the 15-th trim code (Trim code 15). The trimming control circuit 20 may set the trim code range in which the search operation is to be performed in the trim code array according to the comparison result. For example, the trimming control circuit 20 may perform the search operation on trim codes located between the 15-th trim code (Trim code 15) and the 31-st trim code (Trim code 31). The trimming control circuit 20 may output the 23-rd trim code (Trim code 23) corresponding to a median value between the 15-th trim code (Trim code 15) and the 31-st trim code (Trim code 31).

Subsequently, in the same manner as above, the trimming control circuit 20 may output the 27-th trim code (Trim code 27), the 29-th trim code (Trim code 29), and the 28-th trim code (Trim code 28) in order.

The trimming control circuit 20 may determine a trim code (TCODE) corresponding to an analog output value (Output) closest to or substantially equal to the predetermined target value (Target_value) as the final trim code (Fin. Code).

For example, since the predetermined target value (e.g., 640 mV) and the analog output value (e.g., 640 mV) corresponding to the 28-th trim code (Trim code 28) are the same, the trimming control circuit 20 may determine the 28-th trim code (Trim code 28) as the final trim code (Fin. Code).

In the case where the trim code array has monotonically increasing or monotonically decreasing characteristics, the binary search is a method of repeatedly performing a process of measuring an analog output value (Output) corresponding to a trim code (TCODE) located at the center of the search section and reducing the search section by half based on a result of comparing the analog output value (Output) with the target value (Target_value). Therefore, a maximum of log₂N measurements may be required when the number of trim codes (TCODE) is N.

For example, the trimming control circuit 20 may stepwise decrease the trim code search range by repeatedly performing the operation of reducing the trim code search range. In other words, in the case of a 6-bit trim code array, the trimming control circuit 20 may stop the search operation after performing a maximum of 6 search operations.

In FIG. 3, arrows exemplarily illustrate such a binary search method.

As described above, the binary search method of FIG. 3 can determine the final trim code (Fin. Code) with a smaller number of search operations than the linear search method of FIG. 2. Since the binary search method can reduce the number of measurements of the analog output value (Output) compared to the linear search method, time required for the trimming operation can be shortened and test costs can be reduced.

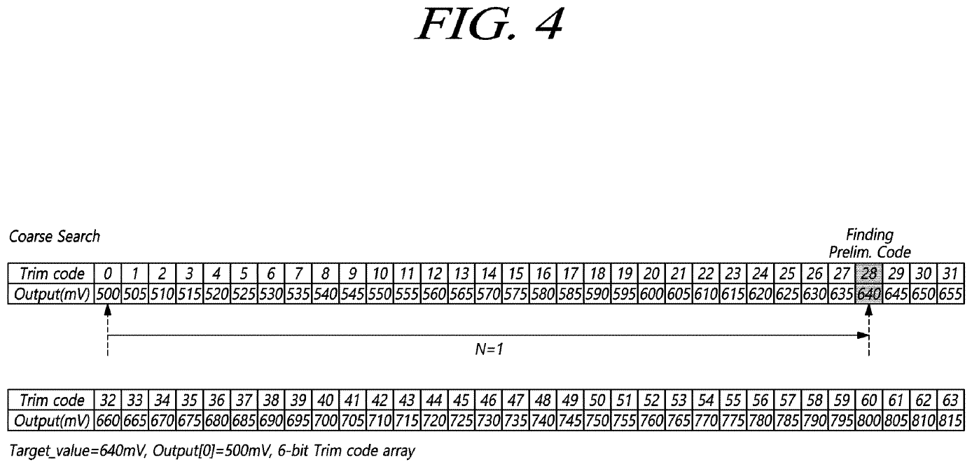

FIG. 4 is a diagram illustrating a coarse search method of the trimming control circuit 20 according to embodiments of the present disclosure.

Referring to FIG. 4, a coarse search method will be described based on the 6-bit trim code array described in FIGS. 2 to 3.

The trimming control circuit according to embodiments of the present disclosure may output a preliminary trim code based on an initial trim code and a code offset, which is a difference or a ratio between two analog output value respectively corresponding to neighboring trim codes, and perform the search operation based on the preliminary trim code.

The trimming control circuit 20 may measure an initial analog output value (e.g., 500 mV) corresponding to the initial trim code (e.g., Trim code 0). The trimming control circuit 20 may output a preliminary trim code (Prelim. Code) based on the initial trim code (Init. Code) by using the code offset, which is a difference between two analog output value (Output) corresponding to neighboring trim codes.

The trimming control circuit 20 may calculate the preliminary trim code (Prelim. Code) by using the initial trim code (Init. Code), the initial analog output value (Output[0]), the target value (Target_value), and the code offset.

For example, under a condition in which the analog output value (Output) linearly changes, the preliminary trim code (Prelim. Code) may be calculated by the following equation:

Preliminary trim code=Initial trim code+(Target value-Initial analog output value)/Code offset.

In the embodiment of FIG. 4, when the target value (Target_value) is 640 mV, the initial analog output value (Output[0]) is 500 mV, and the code offset is 5 mV, the preliminary trim code (Prelim. Code) may be 0+(640-500)/5=28, i.e., the 28-th trim code (Trim code 28).

Since it is assumed that the analog output value (Output) increases at regular intervals (e.g., 5 mV) as the trim code (TCODE) increases in the 6-bit trim code array of FIG. 4, the trimming control circuit 20 may determine the preliminary trim code (Prelim. Code) calculated by the coarse search method as the final trim code (Fin. Code).

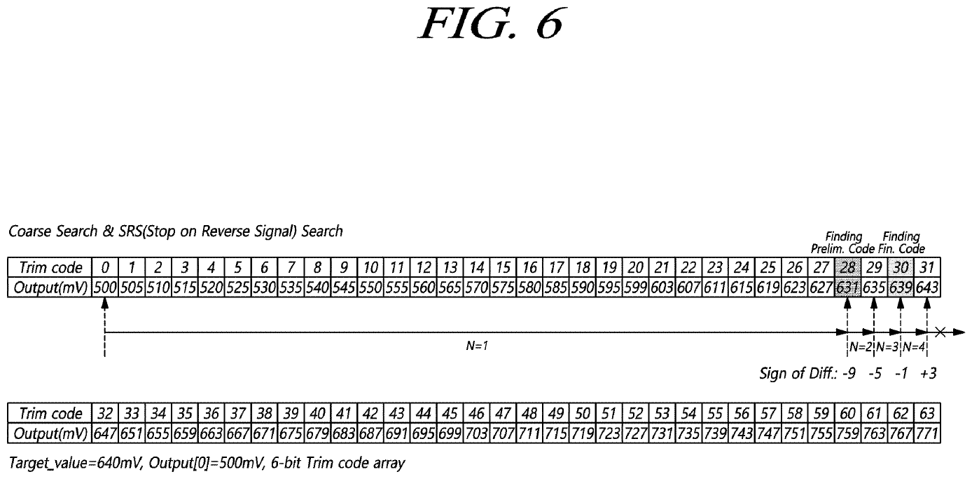

However, when the trim code array includes a non-linear section, that is, when the code offset is different from a value expected in the design of the semiconductor device, the preliminary trim code (Prelim. Code) calculated by the coarse search method may be different from a trim code closest to the target value (Target_value). Accordingly, the trimming control circuit 20 needs to perform an additional fine search based on the preliminary trim code (Prelim. Code). An SRS search (Stop on reverse sign search), which is a type of such a fine search, will be described later in detail with reference to FIG. 6.

The coarse search may calculate the preliminary trim code (Prelim. Code) corresponding to the target value (Target_value) based on the initial analog output value (Output[0]) corresponding to the initial trim code (Init. Code) and the predetermined code offset. Thus, the coarse search can determine a trim code close to the target value (Target_value) as the final trim code (Fin. Code) without measuring all analog output values (Output) corresponding to each of the plurality of trim codes included in the trim code array.

In FIG. 4, arrows exemplarily illustrate such a coarse search method.

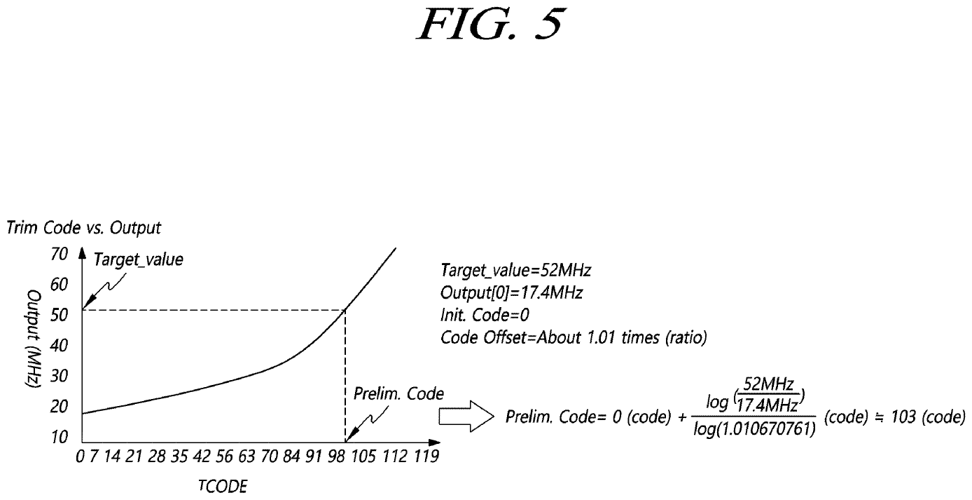

FIG. 5 is a diagram illustrating a coarse search method under a condition in which the analog output value (Output) changes exponentially, according to embodiments of the present disclosure.

Referring to FIG. 5, a graph showing a relationship between the trim code (TCODE) and the analog output value (Output) is exemplarily shown, and the graph may show a characteristic in which the analog output value (Output) non-linearly increases as the trim code (TCODE) increases.

In the graph of FIG. 5, the horizontal axis represents the trim code (TCODE), and the vertical axis represents the analog output value (e.g., output frequency of an oscillator) corresponding to the trim code (TCODE). In addition, a curve of the graph may have a non-linear characteristic in which the analog output value (Output) increases according to a constant ratio as the trim code (TCODE) increases. A vertical dotted line shown in FIG. 5 may represent the preliminary trim code (Prelim. Code), and a horizontal dotted line may represent an analog output value (Output) corresponding to the preliminary trim code (Prelim. Code). In this case, the analog output value (Output) corresponding to the preliminary trim code (Prelim. Code) may be equal to the predetermined target value (Target_value).

For convenience of description, in FIG. 5, the trimming target circuit 10 may be an oscillator (OSC) that generates an output frequency (e.g., a signal with the output frequency). However, embodiments of the present disclosure are not limited thereto.

The trimming control circuit 20 may measure an initial analog output value (e.g., 17.4 MHz) corresponding to the initial trim code (e.g., Trim code 0). The trimming control circuit 20 may output a preliminary trim code (Prelim. Code) based on the initial trim code (Init. Code) by using the code offset (e.g., about 1.01 times), which is a ratio between two analog output value (Output) respectively corresponding to neighboring trim codes.

The trimming control circuit 20 may calculate the preliminary trim code (Prelim. Code) by using the initial trim code (Init. Code), the initial analog output value (Output[0]), the target value (Target_value), and the code offset.

For example, under a condition in which the analog output value (Output) changes exponentially, the preliminary trim code (Prelim. Code) may be calculated by the following equation:

Preliminary trim code=Initial trim code+log(Target value/Initial analog output value)/log(Code offset).

Accordingly, when the target value (Target_value) is 52 MHz, the initial analog output value (Output[0]) is 17.4 MHz, and the code offset is about 1.01 times, the preliminary trim code (Prelim. Code) may be 0+log(52/17.4)/log(1.01)=approximately 103, i.e., the 103rd trim code (Trim code 103).

The trimming control circuit 20 may receive the analog output value (e.g., 52 MHz) corresponding to the preliminary trim code (Prelim. Code) from the trimming target circuit 10. Subsequently, the trimming control circuit 20 may compare the analog output value (e.g., 52 MHz) with the predetermined target value (e.g., 52 MHz), and determine that the two values are substantially equal based on the comparison result.

Since it is assumed that the analog output value (Output) increases at a constant ratio (e.g., about 1.01 times) as the trim code (TCODE) increases in the curve of FIG. 5, the trimming control circuit 20 may determine the preliminary trim code (Prelim. Code) calculated by the coarse search method as the final trim code (Fin. Code).

FIG. 6 is a diagram illustrating a coarse search and a stop on reverse sign search (SRS search) method of the trimming control circuit according to embodiments of the present disclosure.

Referring to FIG. 6, a trimming control circuit (e.g., the trimming control circuit 20 in FIG. 1) according to embodiments of the present disclosure may set a criterion for outputting the trim code according to a sign of a difference value between an analog output value corresponding to the outputted trim code and the target value. For example, the trimming control circuit is configured to output each of the trim codes according to a sign of a difference value between the target value and one of the analog output values corresponding to a previous one of the trim codes.

The trimming control circuit according to embodiments of the present disclosure may stop the search operation when the sign of the difference value is changed. For example, when a first difference value between a target value and a first analog output value corresponding to a first trim code has a first sign, a second difference value between the target value and a second analog output value corresponding to a second trim code has a second sign that is different from the first sign, the trimming control circuit is configured to stop the search operation when the first sign is changed to the second sign.

It is assumed that the trimming control circuit 20 outputs a 6-bit trim code (TCODE). Accordingly, the trimming control circuit 20 may output 64 (=2⁶) trim codes (TCODE). In FIG. 6, a set of a plurality of trim codes used to adjust the analog output value (Output) of the trimming target circuit 10 may be represented as a trim code array.

For convenience of description, in FIG. 6, the trimming target circuit 10 may be a bandgap reference voltage circuit (BGR) or a low drop-out regulator (LDO) configured to generate a reference voltage. However, embodiments of the present disclosure are not limited thereto.

In the embodiment of FIG. 6, an initial analog output value (Output[0]) corresponding to a 0-th trim code (Trim code 0) may be 500 mV, and the target value (Target_value) may be 640 mV. In addition, the code offset in the design stage may be 5 mV. However, it is assumed that the analog output value (Output) increases by 5 mV as the trim code (TCODE) increases by 1 from the 0-th trim code (Trim code 0) to the 19-th trim code (Trim code 19), but the analog output value (Output) increases by 4 mV as the trim code (TCODE) increases by 1 from the 20-th trim code (Trim code 20) to the 63rd trim code (Trim code 63). In other words, it is assumed that the linearity of the trim code array is broken at the 20-th trim code (Trim code 20).

The trimming control circuit 20 may determine the final trim code (Fin. Code) by using a coarse search and an SRS search (stop on reverse sign search) method.

As described in FIG. 4, the trimming control circuit 20 may first output a preliminary trim code (Prelim. Code) by using a coarse search method.

The trimming control circuit 20 may set any one of a minimum value, a maximum value, and a median value of trim codes capable of being output by the trimming control circuit 20 as an initial trim code. In one embodiment, the trimming control circuit 20 may set a 0-th trim code (Trim code 0) corresponding to a minimum value among trim codes included in a trim code array as the initial trim code.

In one embodiment, when a target value (Target_value) is 640 mV, an initial analog output value (Output[0]) is 500 mV, and a code offset is 5 mV, the preliminary trim code (Prelim. Code) may be 0+(640 500)/5=28, i.e., a 28-th trim code (Trim code 28).

The trimming target circuit 10 may generate an analog output value (e.g., 631 mV) corresponding to the preliminary trim code (e.g., Trim code 28). In the coarse search method, one measurement of the analog output value (Output) may be required (N=1). However, the trim code array may include non-linear characteristics in some sections, and accordingly, the output value corresponding to the 28-th trim code (Trim code 28) is 631 mV, which may differ from the target value (e.g., 640 mV).

The trimming control circuit 20 may calculate a difference value between the analog output value (e.g., 631 mV) corresponding to the preliminary trim code (Prelim. Code) and a predetermined target value (e.g., 640 mV). For example, the trimming control circuit 20 may calculate a difference value of 631 mV−640 mV=−9 mV.

The trimming control circuit 20 may set a criterion for outputting the trim code (TCODE) according to a sign of a difference value between the analog output value (Output) corresponding to the outputted trim code (TCODE) and the target value (Target_value). If the sign of the difference value obtained by subtracting the target value (Target_value) from the analog output value (Output) has a negative sign, the trimming control circuit 20 may output the trim code (TCODE) in a direction in which the trim code (TCODE) increases. For example, since the sign of the difference value (e.g., −9 mV) calculated by the trimming control circuit 20 has a negative sign, the trimming control circuit 20 may output the trim code (TCODE) in a direction in which the trim code (TCODE) increases in the trim code array.

Conversely, if the sign of the difference value obtained by subtracting the target value (Target_value) from the analog output value (Output) has a positive sign, the trimming control circuit 20 may output the trim code (TCODE) in a direction in which the trim code (TCODE) decreases.

The trimming control circuit 20 may perform a search operation by using a stop on reverse sign search (SRS search) method following the coarse search method.

The trimming control circuit 20 may perform a search operation of sequentially outputting the trim code (TCODE) by the linear search method described in FIG. 2. For example, the trimming control circuit 20 may perform the search operation of sequentially outputting the trim codes (TCODE) based on the preliminary trim code (e.g., Trim code 28).

For example, the trimming control circuit 20 may perform the search operation in a manner of increasing the trim code (TCODE) by 1 (28→29→30→31→ . . . ) based on the 28-th trim code (Trim code 28).

The trimming control circuit 20 may check the sign of the difference value between the analog output value (Output) generated according to the search operation and the target value (Target_value). The trimming control circuit 20 may stop the search operation when the sign of the difference value between the analog output value (Output) output according to the search operation and the target value (Target_value) is changed. In some embodiments, where a first difference value (e.g., e.g., −1 mV) between a target value (e.g., 640 mV) and a first analog output value (e.g., 639 mV) corresponding to a first trim code (e.g., Trim code 30) has a first sign (e.g., a negative sign) and a second difference value (e.g., +3 mV) between the target value (e.g., 640 mV) and a second analog output value (e.g., 643 mV) corresponding to a second trim code (e.g., Trim code 31) has a second sign (e.g., a positive sign) that is different from the first sign, the trimming control circuit is configured to stop the search operation when the first sign is changed to the second sign.

For example, the trimming control circuit 20 may confirm that the sign of the difference value (e.g., −9 mV) between the analog output value (e.g., 631 mV) corresponding to the 28-th trim code (Trim code 28) and the target value (e.g., 640 mV) is a negative (−) sign. Subsequently, the trimming control circuit 20 may confirm that the sign of the difference value (e.g., −5 mV) between the analog output value (e.g., 635 mV) corresponding to the 29-th trim code (Trim code 29) and the target value (e.g., 640 mV) is a negative (−) sign. Subsequently, the trimming control circuit 20 may confirm that the sign of the difference value (e.g., −1 mV) between the analog output value (e.g., 639 mV) corresponding to the 30-th trim code (Trim code 30) and the target value (e.g., 640 mV) is a negative (−) sign. Subsequently, the trimming control circuit 20 may confirm that the sign of the difference value (e.g., +3 mV) between the analog output value (e.g., 643 mV) corresponding to the 31-st trim code (Trim code 31) and the target value (e.g., 640 mV) is a positive (+) sign. In this case, since the sign of the difference value is changed, the trimming control circuit 20 may stop the search operation of sequentially outputting the trim code (TCODE). Accordingly, the trimming control circuit 20 may not output a 32nd trim code (Trim code 32).

The change in the sign of the difference value described above is not limited to a case where the difference value is changed from a negative (−) sign to a positive (+) sign. In one embodiment, the change in the sign of the difference value may include a case where the difference value is changed from a negative (−) sign to 0. In other words, when the difference value between the analog output value (Output) and the target value (Target_value) becomes 0, the trimming control circuit 20 may determine that the analog output value is equal to the target value and stop the search operation.

Also, in one embodiment, the change in the sign of the difference value may include a case where the difference value is changed from a positive (+) sign to 0.

When the sign of the difference value between the analog output value (Output) and the predetermined target value (Target_value) is changed, the trimming control circuit 20 may determine a trim code (TCODE) corresponding to an analog output value having a smaller absolute difference from the target value (Target_value) between analog output values before and after the sign is changed as a final trim code (Fin. Code).

For example, absolute values of difference values from the target value (e.g., 640 mV) among the analog output value (e.g., 639 mV) corresponding to the 30-th trim code (Trim code 30) and the analog output value (e.g., 643 mV) corresponding to the 31-st trim code (Trim code 31) may be 1 mV and 3 mV, respectively. Accordingly, the trimming control circuit 20 may determine the 30-th trim code (Trim code 30) corresponding to the analog output value (e.g., 639 mV) having the smaller absolute difference from the target value (e.g., 640 mV) as the final trim code (Fin. Code). In other words, the trimming control circuit 20 may determine the 30-th trim code (Trim code 30) as the final trim code (Fin. Code), when the 30-th trim code (Trim code 30) corresponds to the analog output value (e.g., 639 mV) having an absolute difference from the target value smaller than that of the analog output value (e.g., 643 mV) corresponding to the 31-st trim code (Trim code 31).

In the SRS search (stop on reverse sign search) method, three measurements of the analog output value may be required (N=2 to 4). Accordingly, in this example, the final trim code (Fin. Code) can be determined only with a total of four search operations, including one coarse search and three SRS searches.

In FIG. 6, arrows exemplarily illustrate such a coarse search method and an SRS search (stop on reverse sign search) method.

According to the disclosure described above, the coarse search and SRS search (stop on reverse sign search) method can determine the final trim code (Fin. Code) with a smaller number of search operations compared to the linear search method of FIG. 2 or the binary search method of FIG. 3. Accordingly, such a coarse search and SRS search (stop on reverse sign search) method according to embodiments of the present disclosure can improve search efficiency and accuracy of determining the final trim code.

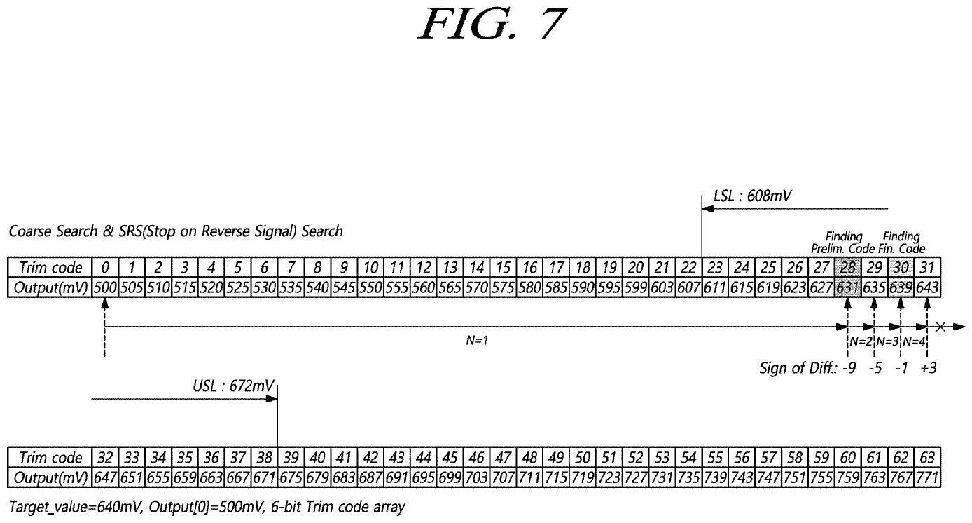

FIG. 7 is a diagram illustrating a coarse search and SRS search (stop on reverse sign search) method of a trimming control circuit according to embodiments of the present disclosure.

Referring to FIG. 7, a search operation according to embodiments of the present disclosure may be performed within a predetermined code range based on a target value.

A trimming control circuit according to embodiments of the present disclosure may stop the search operation when a predetermined maximum number of trim code outputs is reached. In other words, a trimming control circuit according to embodiments of the present disclosure may stop the search operation when a predetermined maximum number of trim codes have been output therefrom.

A trimming control circuit according to embodiments of the present disclosure may re-perform the search operation when an analog output value corresponding to a final trim code exceeds a predetermined tolerance range from a target value.

The trimming control circuit 20 may perform the search operation within a predetermined code range based on a predetermined target value (Target_value). The predetermined code range may be defined by trim codes corresponding to a lower specification limit (LSL) and an upper specification limit (USL) calculated by applying a predetermined tolerance range to the target value (Target_value).

For example, when the target value (Target_value) is 640 mV and the tolerance range is set to ±5%, a lower specification limit (LSL) and an upper specification limit (USL) may be calculated as 608 mV and 672 mV, respectively, based on the target value (e.g., 640 mV), and a set of trim codes (e.g., Trim code 23 to Trim code 38) corresponding to analog output values (Output) greater than or equal to the lower specification limit (LSL; 608 mV) and less than or equal to the upper specification limit (USL; 672 mV) may be defined as the predetermined code range.

The trimming control circuit 20 may stop the search operation when the predetermined maximum number of trim code outputs is reached. In other words, the trimming control circuit 20 may stop the search operation when the predetermined maximum number of trim codes have been output therefrom. The predetermined maximum number of trim code outputs may be set as a limit value for repeated execution of the search operation. When the maximum number of trim code outputs is reached, the trimming control circuit 20 may stop the search operation without outputting any additional trim code (TCODE).

Accordingly, it is possible to prevent the search operation from being excessively repeated due to unexpected condition changes or abnormal output characteristics during the trim code search process.

The trimming control circuit 20 may re-perform the search operation when the analog output value (Output) corresponding to the final trim code (Fin. Code) exceeds a predetermined tolerance range from the target value (Target_value). The predetermined tolerance range may be a reference range centered on the target value (Target_value). The predetermined tolerance range may be dynamically set in a design stage or a test stage of a semiconductor device according to design specifications, operating conditions, circuit characteristics, or required precision of the semiconductor device.

In one embodiment, the tolerance range may be set as a relative ratio to the target value (Target_value). In one embodiment, the tolerance range may be set based on an absolute value.

According to the disclosure described above, efficiency and reliability of the search operation can be improved through search range limitation, an upper limit on the number of searches, and tolerance-based re-search.

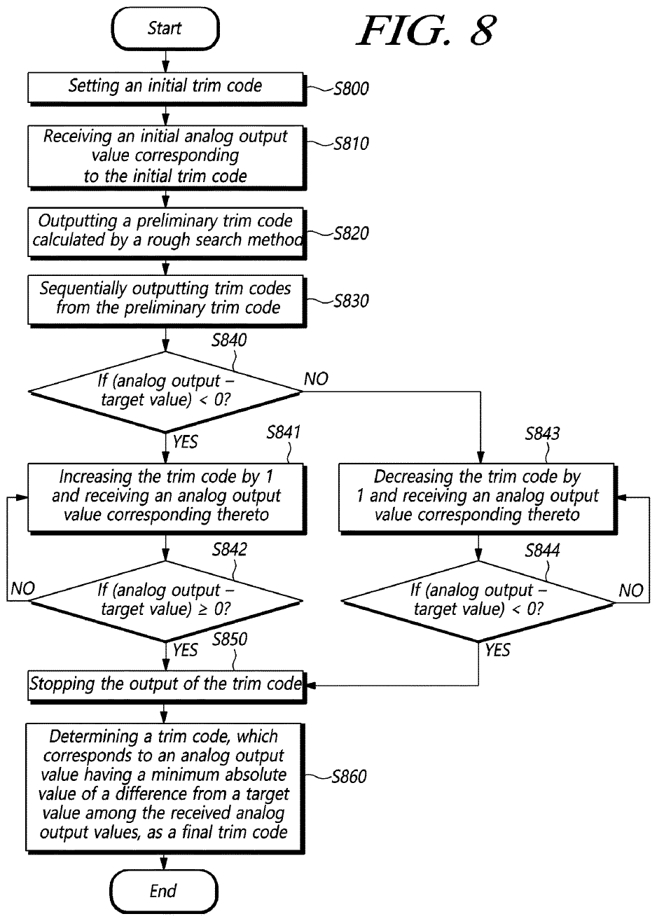

FIG. 8 is a flowchart illustrating a trim code search process according to a coarse search and SRS search (stop on reverse sign search) method of a trimming control circuit according to embodiments of the present disclosure.

Referring to FIG. 8, the trimming control circuit 20 may set an initial trim code (S800). The initial trim code may be set to any one of a minimum value, a maximum value, and a median value of trim codes capable of being output by the trimming control circuit.

In one embodiment, assuming that the trimming control circuit 20 can output a 6-bit trim code, the trimming control circuit 20 may output a total of 64 trim codes, and may set at least one of the total 64 trim codes as the initial trim code.

The trimming control circuit 20 may receive an initial analog output value (Output[0]) corresponding to the initial trim code (Init. Code) from the trimming target circuit 10 (S810). The trimming control circuit 20 may calculate a preliminary trim code (Prelim. Code) by the coarse search method described in FIGS. 4 to 5. As described in FIG. 4 to FIG. 5, the preliminary trim code (Prelim. Code) may be calculated by using a code offset, which is a difference or a ratio between two analog output values (Output) respectively corresponding to neighboring trim codes, the initial trim code (Init. Code), the initial analog output value (Output[0]), and a predetermined target value (Target_value).

The trimming control circuit 20 may output the preliminary trim code (Prelim. Code) calculated by the coarse search method (S820). The trimming control circuit 20 may receive an analog output value (Output) corresponding to the preliminary trim code (Prelim. Code) from the trimming target circuit 10. The trimming control circuit 20 may calculate a difference value between the analog output value (Output) corresponding to the preliminary trim code (Prelim. Code) and the predetermined target value (Target_value). In one embodiment, if the analog output value (Output) corresponding to the preliminary trim code (Prelim. Code) and the predetermined target value (Target_value) are substantially the same, the trimming control circuit 20 may stop the search operation of outputting the trim code (TCODE) and determine the preliminary trim code (Prelim. Code) as the final trim code (Fin. Code).

The trimming control circuit 20 may perform a search operation of sequentially outputting a plurality of trim codes (TCODE) from the preliminary trim code (Prelim. Code) (S830). The trimming control circuit 20 may receive an analog output value (Output) corresponding to the trim code (TCODE) and outputting from the trimming target circuit 10.

The trimming control circuit 20 may check whether the received analog output value (Output) is smaller than the predetermined target value (Target_value) (S840). If the received analog output value (Output) is smaller than the predetermined target value (Target_value), the trimming control circuit 20 may receive an analog output value (Output) corresponding thereto while increasing the trim code (TCODE) by 1 (S841). For example, the trimming control circuit 20 may output the increased trim code (TCODE) to generate an analog output value (Output) increased from the previous analog output value received by the trimming control circuit 20. The trimming control circuit 20 may check whether the increased analog output value (Output) is greater than or equal to the predetermined target value (Target_value) (S842). If the received analog output value (Output) is greater than or equal to the predetermined target value (Target_value), the trimming control circuit 20 may stop outputting the trim code (TCODE) (S850).

If the received analog output value (Output) is greater than or equal to the predetermined target value (Target_value), the trimming control circuit 20 may receive an analog output value (Output) corresponding thereto while decreasing the trim code (TCODE) by 1 (S843). For example, the trimming control circuit 20 may output the decreased trim code (TCODE) to generate an analog output value (Output) decreased from the previous analog output value received by the trimming control circuit 20. The trimming control circuit 20 may check whether the decreased analog output value (Output) is smaller than the predetermined target value (Target_value) (S844). If the received analog output value (Output) is smaller than the predetermined target value (Target_value), the trimming control circuit 20 may stop outputting the trim code (TCODE) (S850).

The trimming control circuit 20 may determine a trim code (TCODE) corresponding to an analog output value (Output) having a smallest absolute difference from the target value (Target_value) among the received analog output values as a final trim code (Fin. Code) (S860).

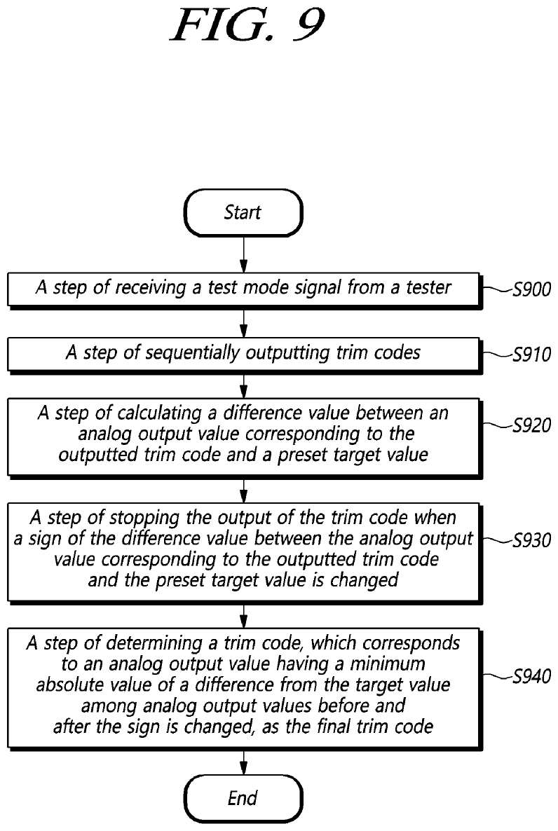

FIG. 9 is a diagram illustrating a method of testing a semiconductor device 100 according to embodiments of the present disclosure.

Referring to FIG. 9, the method of testing a semiconductor device 100 may include receiving a test mode signal from a tester 150 (S900).

The test mode signal may be a control signal for controlling the semiconductor device to switch to a test mode distinguished from a normal operation mode. In one embodiment, the test mode signal may act as a condition for starting the trim code search operation, and if the corresponding signal is not activated, the trim code search operation may not be performed. In one embodiment, the test mode signal may be a signal applied in a manufacturing stage or a test stage of a semiconductor device, but embodiments of the present disclosure are not limited thereto, and it may be applied for a trim code correction operation in a normal operation mode.

Accordingly, the semiconductor device can dynamically adjust the trim code (TCODE) to compensate for a deviation of the analog output value (Output) according to a change in operating conditions as well as an initial test stage.

The method of testing a semiconductor device may include sequentially outputting a plurality of trim codes (TCODE) when the test mode signal is received (S910).

The sequentially outputting the trim code (TCODE) described above may further include outputting a preliminary trim code (Prelim. Code) based on an initial trim code and a code offset, which is a difference or a ratio between two of the analog output values (Output) respectively corresponding to neighboring trim codes, and sequentially outputting the trim codes (TCODE) based on the preliminary trim code (Prelim. Code). In addition, the sequentially outputting the trim code (TCODE) described above may further include outputting the trim codes (TCODE) within a predetermined code range based on a predetermined target value (Target_value).

The method of testing a semiconductor device may include calculating a difference value between an analog output value (Output) corresponding to the outputted trim code (TCODE) and a predetermined target value (Target_value) (S920). The method of testing a semiconductor device may further include setting a criterion for outputting the trim code according to a sign of a difference value between the analog output value and the target value.

The method of testing a semiconductor device may include stopping outputting the trim code (TCODE) when the sign of the calculated difference value is changed (S930).

The method of testing a semiconductor device may include, when the sign of the calculated difference value is changed, determining a trim code (TCODE) corresponding to an analog output value (Output) having a smallest absolute difference from the target value (Target_value) among analog output values before and after the sign is changed as a final trim code (Fin. Code) (S940). The method of testing a semiconductor device may include transmitting a test result including information on the final trim code (Fin. Code) to a tester.

In some embodiments, the method may include generating a plurality of analog output values according to the plurality of trim codes, where the analog output values including first and second analog output values respectively correspond to first and second trim codes of the trim codes. Such a method may include, at S920, determining a first difference value between the first analog output value and the target value and a second difference value between the second analog output value and the target value. The method may include, at S930, stopping outputting the trim codes when a first sign of the first difference value is changed to a second sign of the second difference value. The method may include, at S940, determining the first trim code as a final trim code, when the first sign of the first difference value is different from the second sign of the second difference value and an absolute value of the first difference value is smaller than that of the second difference value.

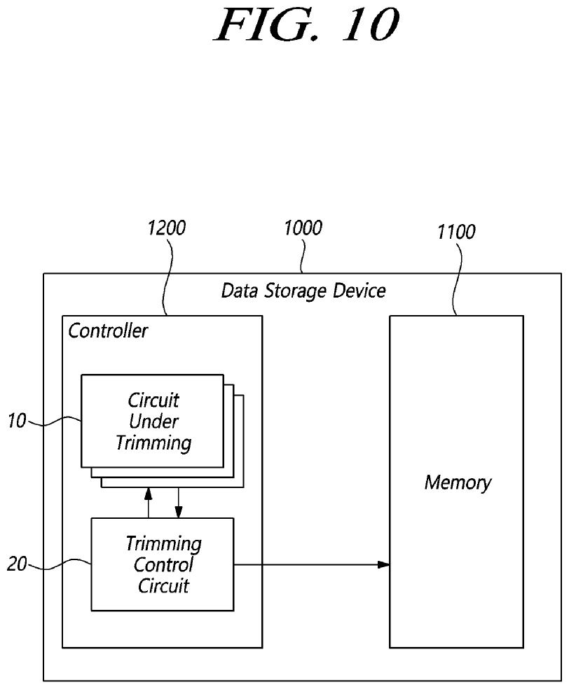

FIG. 10 is a diagram illustrating a schematic configuration of a data storage device according to embodiments of the present disclosure.

Referring to FIG. 10, a data storage device 1000 according to embodiments of the present disclosure may include at least one memory 1100 and a controller 1200 comprising at least one trimming target circuit 10 configured to generate an analog output value according to a trim code and a trimming control circuit 20 configured to output the trim code, wherein the trimming control circuit is configured to perform a search operation of sequentially outputting the trim code, receive the analog output value corresponding to the trim code and outputting from the at least one trimming target circuit 10, and, when a sign of a difference value between the received analog output value and a predetermined target value is changed, determine a trim code corresponding to an analog output value having a smallest absolute difference from the target value among analog output values before and after the sign is changed as a final trim code. For example, at least one trimming target circuit 10 may generate a plurality of analog output values according to a plurality of trim codes, respectively, and a trimming control circuit 20 may perform a search operation of sequentially outputting the trim codes, and receive the analog output values corresponding to the trim codes and outputting from the at least one trimming target circuit 10. When a first difference value between a target value and a first analog output values corresponding to a first trim code has a first sign, a second difference value between the target value and a second analog output value corresponding to a second trim code has a second sign that is different from the first sign, and an absolute value of the first difference value is smaller than that of the second difference value, the trimming control circuit 20 may determine the first one of the trim codes as a final trim code.

A controller 1200 according to embodiments of the present disclosure may provide the final trim code to at least one memory 1100.

A trimming control circuit 20, or a trimming target circuit 10, or both according to embodiments of the present disclosure may be embedded in a controller as a built-in self-test (BIST) device.

A trimming control circuit 20 according to embodiments of the present disclosure may output a preliminary trim code based on an initial trim code and a code offset, which is a difference or a ratio between two of analog output values respectively corresponding to neighboring trim codes, and perform the search operation based on the preliminary trim code.

The data storage device 1000 includes a memory 1100 and a controller 1200, and may operate under control of a host device (not shown).

The controller 1200 may control the memory 1100 in response to a request from the host device (not shown). For example, the controller 1200 may cause data to be programmed into the memory 1100 according to a write request of the host device (not shown). Also, in response to a read request of the host device (not shown), the controller 1200 may provide data recorded in the memory 1100 to the host device (not shown).

The memory 1100 may record data or output recorded data under control of the controller 1200. The memory 1100 may be configured as a volatile or non-volatile memory. In one embodiment, the memory 1100 may be implemented in various types such as NAND flash memory, 3D NAND flash memory, NOR flash memory, resistive RAM, phase-change memory, magnetoresistive memory, ferroelectric memory, or spin-transfer torque memory. Also, the memory 1100 may be implemented in a three-dimensional array structure.

The memory 1100 may include a plurality of memory blocks. The memory 1100 may include a memory cell array including a plurality of memory cells configured to store data, and the memory cell array may exist within the memory block.

The memory 1100 may operate in response to control of the controller 1200. Operations of the memory 1100 may include, for example, a program operation (also referred to as a “write operation”), an erase operation, and a read operation.

The memory 1100 may generate an analog output value (Output) by receiving a trim code (TCODE) from the controller 1200 to perform a program, erase, or read operation under control of the controller 1200.

The controller 1200 may include a trimming target circuit 10 and a trimming control circuit 20.

The trimming target circuit 10 may generate the analog output value (Output) according to the trim code (TCODE). In this case, the analog output value (Output) may be at least one of voltage, current, or frequency.

The trimming target circuit 10 may be included in the controller 1200, as shown in FIG. 10, or may be included in at least one memory 1100. However, various embodiments of the present disclosure are not limited thereto.

The trimming target circuit 10 may be located inside the controller 1200. The trimming target circuit 10 may be embedded in the controller 1200 as a built-in self-test (BIST) device. For example, one or more of a bandgap reference voltage circuit (BGR), a low drop-out regulator (LDO), an oscillator (OSC), and a current generation circuit operating inside the controller 1200 may be included in the trimming target circuit 10.

Although not shown in FIG. 10, in some embodiments, the trimming target circuit 10 may be located outside the controller 1200. For example, one or more of an internal voltage generation circuit included in a non-volatile memory, a voltage generation circuit for driving a word line/bit line, and a reference clock generation circuit may be included in the trimming target circuit 10.

The trimming control circuit 20 may output the trim code (TCODE) provided to the trimming target circuit 10. The trimming control circuit 20 may determine the final trim code (Fin. Code) based on a result of comparing a predetermined target value (Target_value) with the analog output value (Output) generated corresponding to the outputted trim code (TCODE).

The trimming target circuit 10 generates the analog output value (Output) according to the trim code (TCODE), but the analog output value may have a deviation from the target value (Target_value) due to process variation, power fluctuation, temperature change, or device characteristic change. Therefore, the trimming control circuit 20 may perform a control function of searching for and determining the trim code (TCODE) to reduce the deviation.

The trimming control circuit 20 may be embedded in the controller 1200 as a built-in self-test (BIST) device. Accordingly, various tests including a trimming operation can be performed on-chip. However, embodiments of the present disclosure are not limited thereto, and the trimming control circuit 20 may be connected to a tester (e.g., the tester 150 in FIG. 1).

The trimming control circuit 20 may perform one or more of a linear search, a binary search, a coarse search, and an SRS search (stop on reverse sign search) as a trim code search operation.

In one embodiment, the trimming control circuit 20 may perform a coarse search of calculating a preliminary trim code (Prelim. Code) by using a code offset, which is a difference or a ratio between analog output values (Output) respectively corresponding to neighboring trim codes. Subsequently, the trimming control circuit 20 may perform an SRS search (stop on reverse sign search) of sequentially increasing or decreasing the trim code (TCODE) until a sign of a difference value between the analog output value (Output) received from the trimming target circuit 10 and a predetermined target value (Target_value) is changed.

Also, the trimming control circuit 20 may apply search control conditions, such as performing a search within a predetermined trim code range based on the target value (Target_value), stopping the search when a predetermined maximum number of trim codes have been output therefrom, or re-performing the search when an analog output value (Output) corresponding to the final trim code (Fin. Code) exceeds a tolerance range from a target value (Target_value).

The final trim code (Fin. Code) determined by the trimming control circuit 20 is stored in a control logic (not shown) of the memory 1100 and may be used for internal operations of the memory 1100 such as program, erase, and read. The control logic (not shown) may control general operations of the memory 1100 based on control signals provided from an external device. For example, the control logic (not shown) may control program, erase, and read operations of the memory 1100.

In one embodiment, the trim code (TCODE) provided from the controller 1200 may be stored in a read only memory (ROM) within the control logic (not shown), and a voltage generator of the memory 1100 may generate an internal voltage based on the trim code (TCODE).

According to the disclosure described above, the controller 1200 determines the final trim code (Fin. Code) through the trimming control circuit 20 and applies the final trim code (Fin. Code) to the operation of the memory 1100, so that an internal voltage generated in the memory 1100 or peripheral circuits under control of the controller may be set based on a consistent trim code (TCODE).

Although some embodiments of the disclosed technology have been described with particular specifics and varying details for illustrative purposes, those skilled in the art will appreciate that various modifications, additions and substitutions may be made based on what is disclosed or illustrated in the present disclosure without departing from the spirit and scope the present disclosure. Furthermore, the above-described embodiments may be combined to form additional embodiments.

What is claimed is:

1. A semiconductor device comprising:
at least one trimming target circuit configured to generate a plurality of analog output values according to a plurality of trim codes; and
a trimming control circuit configured to perform a search operation of sequentially outputting the trim codes, and receive the analog output values corresponding to the trim codes and outputting from the at least one trimming target circuit, the analog output values including first and second analog output values respectively corresponding to first and second trim codes of the trim codes,
wherein the trimming control circuit is configured to determine the first trim code as a final trim code, when a first difference value between a target value and the first analog output value corresponding to the first trim code has a first sign, a second difference value between the target value and the second analog output value corresponding to the second trim code has a second sign that is different from the first sign, and an absolute value of the first difference value is smaller than that of the second difference value.

2. The semiconductor device of claim 1, wherein the trimming control circuit is configured to set a criterion for outputting each of the trim codes according to a sign of a difference value between the target value and one of the analog output values corresponding to a previous one of the trim codes.

3. The semiconductor device of claim 1, wherein the trimming control circuit is configured to stop the search operation when the first sign is changed to the second sign.

4. The semiconductor device of claim 1, wherein the trimming control circuit is configured to output a preliminary trim code based on an initial trim code and a code offset, the code offset is a difference or a ratio between two of the analog output values respectively corresponding to neighboring trim codes, and the trimming control circuit is configured to perform the search operation based on the preliminary trim code.

5. The semiconductor device of claim 4, wherein the initial trim code is set to any one of a minimum value, a maximum value, and a median value of trim codes capable of being output by the trimming control circuit.

6. The semiconductor device of claim 1, wherein the search operation is performed within a predetermined code range based on the target value.

7. The semiconductor device of claim 1, wherein the trimming control circuit is configured to stop the search operation when a predetermined maximum number of trim codes have been output therefrom.

8. The semiconductor device of claim 1, wherein the trimming control circuit is configured to re-perform the search operation when the first analog output value corresponding to the final trim code exceeds a predetermined tolerance range from the target value.

9. The semiconductor device of claim 8, wherein the trimming control circuit further comprises a trim code temporary storage unit configured to store the final trim code, and to set the final trim code stored in the trim code temporary storage unit as an initial trim code before re-performing the search operation.

10. The semiconductor device of claim 1, wherein the trimming target circuit is an analog signal generation circuit configured to generate at least one of voltage, current, or frequency.

11. A method of testing a semiconductor device, comprising:
receiving a test mode signal from a tester;
sequentially outputting a plurality of trim codes when the test mode signal is received;
generating a plurality of analog output values according to the plurality of trim codes, the analog output values including first and second analog output values respectively corresponding to first and second trim codes of the trim codes;
determining a first difference value between the first analog output value and a target value and a second difference value between the second analog output value and the target value; and
determining the first trim code as a final trim code when a first sign of the first difference value is different from a second sign of the second difference value and an absolute value of the first difference value is smaller than that of the second difference value.

12. The method of claim 11, further comprising setting a criterion for outputting each of the trim codes according to a sign of a difference value between the target value and one of the analog output values corresponding to a previous one of the trim codes.

13. The method of claim 11, further comprising stopping outputting the trim codes when the first sign is changed to the second sign.

14. The method of claim 11, wherein sequentially outputting the predetermined trim code comprises:
outputting a preliminary trim code based on an initial trim code and a code offset, wherein the code offset is a difference or a ratio between two of the analog output values respectively corresponding to neighboring trim codes; and
sequentially outputting the trim codes based on the preliminary trim code.

15. The method of claim 11, wherein sequentially outputting the predetermined trim code comprises outputting the trim codes within a predetermined code range based on the target value.

16. The method of claim 11, further comprising transmitting a test result including information on the final trim code to the tester.

17. A data storage device comprising:
at least one memory; and
a controller including at least one trimming target circuit configured to generate a plurality of analog output values according to a plurality of trim codes, and a trimming control circuit configured to output the trim codes,
wherein the trimming control circuit is configured to:
perform a search operation of sequentially outputting the trim codes;
receive the analog output values corresponding to the trim codes and outputting from the at least one trimming target circuit, the analog output values including first and second analog output values respectively corresponding to first and second trim codes of the trim codes; and
determine the first trim code as a final trim code, when a first difference value between a target value and the first analog output value has a first sign, a second difference value between the target value and the second analog output value has a second sign that is different from the first sign, and an absolute value of the first difference value is smaller than that of the second difference value.

18. The data storage device of claim 17, wherein the controller is configured to provide the final trim code to the at least one memory.

19. The data storage device of claim 17, wherein the trimming control circuit, or the trimming target circuit, or both, are embedded in the controller as a built-in self-test (BIST) device.

20. The data storage device of claim 17, wherein the trimming control circuit is configured to output a preliminary trim code based on an initial trim code and a code offset, the code offset is a difference or a ratio between two of the analog output values respectively corresponding to neighboring trim codes, and the trimming control circuit is configured to perform the search operation based on the preliminary trim code.
